(19) United States
(12) Patent Application Publication
(10) Pub. No.: US 2024/0393679 A1
(43) Pub. Date: Nov. 28, 2024

(54) DEVICE AND METHOD FOR CLEANING PELLICLE FRAME AND MEMBRANE

(71) Applicant: Taiwan Semiconductor Manufacturing Company, Ltd., Hsinchu (TW)

(72) Inventors: Kun-Lung Hsieh, Kaohsiung (TW); Tzu Han Liu, Tainan (TW); Hao-En Luo, Taipei (TW); Chih-Wei Wen, Tainan (TW)

(21) Appl. No.: 18/788,332

(22) Filed: Jul. 30, 2024

Related U.S. Application Data
(62) Division of application No. 17/721,538, filed on Apr. 15, 2022.

(51) Int. Cl. G03F 1/82; G03F 1/64

(52) U.S. Cl. CPC G03F 1/82; G03F 1/64

(57) ABSTRACT

In pellicle cleaning, a gas is flowed on a pellicle using at least one gas nozzle. During the flowing, the pellicle is moved respective to the at least one gas nozzle. During the flowing, the pellicle is exposed to ionized gas generated by at least one alpha ionizer. Also during the flowing, an ultrasonic wave is applied to the pellicle using an ultrasound transducer or transducer array. The gas nozzle may have a nozzle aperture comprising a slit or a linear array of apertures arranged parallel with a pellicle membrane of the pellicle.

This application is a Divisional of U.S. Ser. No. 17/721,538 filed Apr. 15, 2022, which is incorporated herein by reference in its entirety.

### BACKGROUND

The following relates to semiconductor fabrication arts, semiconductor photolithography arts, extreme ultraviolet (EUV) photolithography arts, pellicle maintenance arts, and related arts.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 and FIG. 2 diagrammatically illustrate side and front views, respectively, of a pellicle cleaning apparatus.

FIG. 3 diagrammatically illustrates a side view of a gas nozzle suitably used in the pellicle cleaning apparatus of FIGS. 1 and 2 in accordance with some embodiments.

FIG. 4 diagrammatically illustrates a nozzle aperture suitably implemented by the gas nozzle of FIG. 3 in accordance with some embodiments.

FIG. 5 diagrammatically illustrates perspective views of the first blade (upper views) and second blade (lower views) of a gas nozzle such as that of FIG. 3 having a nozzle aperture such as that of FIG. 4.

FIG. 6 diagrammatically illustrates the outside surface of the first blade (top view) and the inside surface of the first blade (bottom view) of the gas nozzle depicted in FIG. 5.

FIG. 7 diagrammatically illustrates the outside surface of the second blade (top view) and the inside surface of the second blade (bottom view) of the gas nozzle depicted in FIG. 5.

FIG. 8 shows a method of cleaning a pellicle.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Photolithographic patterning processes use a reticle (i.e. photomask) that includes a desired mask pattern. The reticle may be a reflective mask or a transmission mask. In the process, ultraviolet light is reflected off the surface of the reticle (for a reflective mask) or transmitted through the reticle (for a transmission mask) to transfer the pattern to a photoresist on a semiconductor wafer. The exposed portion of the photoresist is photochemically modified. After the exposure, the resist is developed to define openings in the resist, and one or more semiconductor processing steps (e.g. etching, epitaxial layer deposition, metallization, et cetera) are performed which operate on those areas of the wafer surface exposed by the openings in the resist. After this semiconductor processing, the resist is removed by a suitable resist stripper or the like.

The minimum feature size of the pattern is limited by the light wavelength. Deep ultraviolet (UV) lithography, for example using a wavelength of 193 nm or 248 nm in some standard deep UV platforms, typically employs transmission masks and provides a smaller minimum feature size than lithography at longer wavelengths. Extreme ultraviolet (EUV) light, which spans wavelengths from 124 nanometers (nm) down to 10 nm, is currently being used to provide even smaller minimum feature size, such as 5 nm node devices or even smaller. At shorter wavelengths, particle contaminants on the reticle can cause defects in the transferred pattern. Thus, a pellicle is used to protect the reticle from such particles. The pellicle includes a pellicle membrane which is attached to a mounting frame, for example by an adhesive. The mounting frame supports the pellicle membrane over the reticle. Any contaminating particles which land on the pellicle membrane are thus kept out of the focal plane of the reticle, thus reducing or preventing defects in the transferred pattern.

By way of nonlimiting illustration, an EUV photomask used in EUV photolithography may suffer impacts of particles of materials such as silicon oxide, metal oxide, and organic particles falling on the pellicle. While some particles may fall onto the pellicle during mounting onto the mask, the dominant particle contamination vector is particles falling on the mask while it is used in an EUV scanner for EUV photolithography. For example, a typical EUV scanner light source is a laser-produced plasma (LPP) light source in which a pulsed laser beam is timed to strike droplets of a stream of tin droplets, and this process can generate tin particles that can pass through the intermediate focus (IF) of the LPP light source and impinge on the pellicle of the reticle. While the pellicle reduces the adverse impact on the photolithographically processed wafer, it cannot completely prevent such adverse impact.

Another failure mode can occur due to particle contamination that can enter the space between the reticle membrane and the pellicle membrane. This is possible because the pellicle is usually not hermetically sealed to the reticle, but rather the reticle frame by which the pellicle membrane is mounted over the reticle surface typically has vent holes to equalize pressure on opposite sides of the thin and fragile pellicle membrane. Particles can thus ingress through the vent holes into the space defined between the reticle surface and the pellicle membrane. These particles are of particular concern, both because they are closer to the focal plane of the reticle and because if these particles dislodge then they can then fall onto and adhere to the surface of the reticle, leading to wafer defects.

Disclosed herein are pellicle cleaning apparatuses and methods that effectively clean the pellicle with the advantageously reduced gas flow rates. The disclosed approaches in some embodiments employ two or (in the illustrative examples) three coadunate physical forces that operate synergistically to increase the particle removal efficiency in cleaning the pellicle membrane and frame.

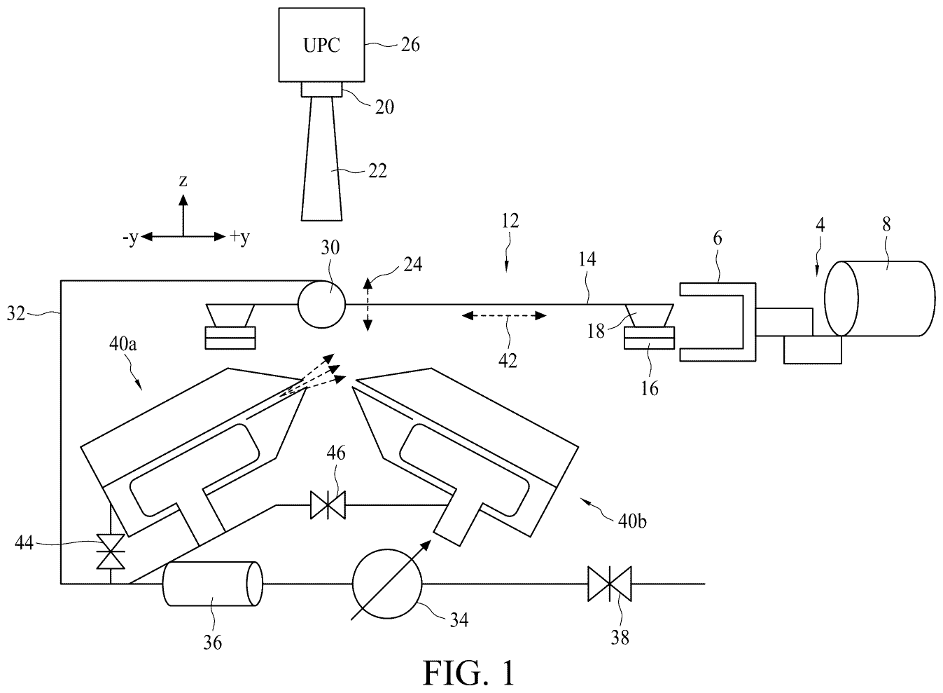

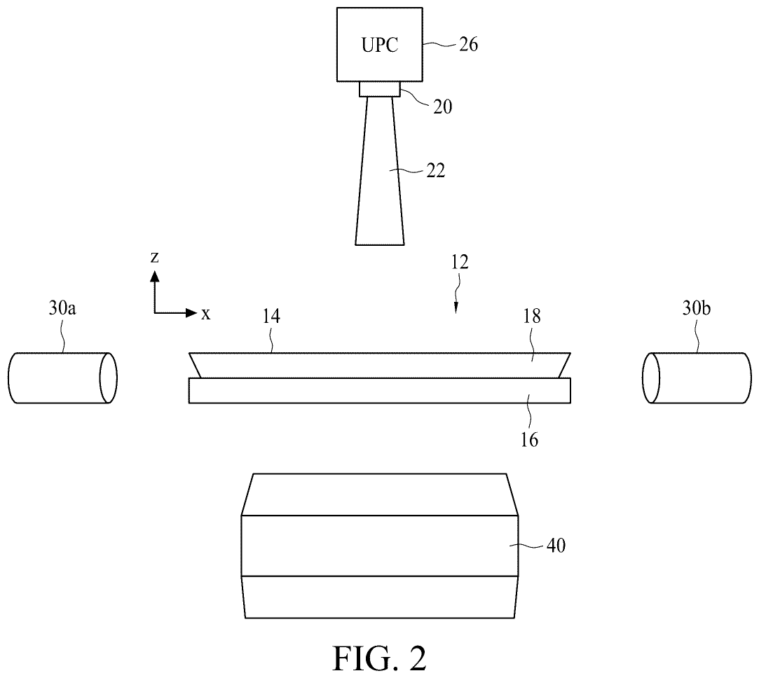

FIG. 1 and FIG. 2 diagrammatically illustrate side and front views, respectively, of a pellicle cleaning apparatus A pellicle holder 4 (diagrammatically indicated only in FIG. 1), which in the illustrative example includes a clamp 6 and a motor 8, holds a pellicle 12 to be cleaned. The pellicle 12 includes a pellicle membrane 14 mounted on a pellicle frame 16 by an adhesive layer 18. In some non-limiting illustrative embodiments, the pellicle 12 is intended for use in protecting a reticle or photomask that is deployed in EUV lithography operating a an EUV light wavelength, for example from 124 nm to 10 nm, including about 13.5 nm.

Without loss of generality, and for convenience in describing spatial relationships herein, an x-y-z coordinate system is shown in FIGS. 1 and 2. Specifically, the side view of FIG. 1 depicts the y-z plane, while the front view of FIG. 2 depicts the x-z plane. Furthermore, and again without loss of generality, a positive direction (+y) and a negative direction (−y) are indicated in FIG. 1. With particular reference to FIG. 1, the diagrammatically illustrated pellicle holder 4 includes an illustrative clamp 6 or other holding mechanism by which the pellicle holder 4 holds the pellicle 12, and a motor 6 or other mechanism for translating the held pellicle 12 in a reciprocating movement in a positive direction (illustrative +y direction) and a negative direction (illustrative −y direction).

The pellicle membrane 14 is typically thin to enable it to transmit EUV light. For example, in some nonlimiting illustrative embodiments the pellicle membrane may have a thickness of 10-100 nanometers, although greater or lesser thicknesses are contemplated. The pellicle membrane 14 may be made of various materials, such as by way of nonlimiting illustrative example graphene, carbon nanotubes, or so forth. It will be appreciated that the pellicle membrane 14 is relatively fragile, due to the thinness of the pellicle membrane 14. Without loss of generality, the illustrative pellicle 12 of FIGS. 1 and 2 is positioned with the pellicle membrane 14 in an x-y plane, so that the z-direction is transverse to (i.e. normal to) the plane of the membrane 14.

The pellicle frame 16 supports the fragile pellicle membrane 14 over the surface of the reticle at a separation distance sufficient to take the pellicle membrane 14 outside the focal plane of the light impinging on the reticle surface during the lithography process. For example, the pellicle frame 16 may have a thickness of several millimeters (mm) to position the pellicle membrane 14 over the reticle surface, in some nonlimiting illustrative embodiments. The pellicle frame 16 can be made from suitable materials such as anodized aluminum, stainless steel, plastic, silicon (Si), titanium, silicon dioxide, aluminum oxide (Al₂O₃), or titanium dioxide (TiO₂). Typically, the pellicle frame 16 is a rectangular or other encircling frame that coincides with and supports the full perimeter of the pellicle membrane 14. This is generally shown in FIG. 2; however, in FIG. 1 a side sectional view of the pellicle 12 is shown which cuts through two sides of the pellicle frame 16. Vent holes (not shown) may be present in the pellicle frame 16 for equalizing pressure on both sides of the pellicle membrane 14 when the pellicle 12 is secured to a reticle (not shown) by the pellicle frame 16. This is beneficial since a pressure difference across the pellicle membrane 14 could potentially damage the thin and fragile pellicle membrane 14. However, it will be appreciated that such vent holes can permit ingress of particles between the pellicle membrane 14 and the reticle surface on which it is mounted during use of the reticle in for photolithography tasks. Particles entering the space between the reticle and the pellicle membrane 14 can adhere to the pellicle membrane 14, and can also adhere to the pellicle frame 16. These particles may also possess some static electrical charge, which can promote particle adhesion to the pellicle membrane 14 and/or frame 16. Particles adhering “inside” the pellicle 12, that is, adhering to the inside of the frame 16 or to the surface of the pellicle membrane 14 that faces the reticle surface, can be particularly problematic as these particles can later dislodge from the pellicle 12 and subsequently adhere on the reticle surface, where they are in the focal plane of the reticle and can introduce wafer defects during the photolithography process.

The adhesive layer 18 is used to secure the pellicle membrane 14 to the pellicle frame 16. Suitable adhesives may, by way of nonlimiting illustration, include a silicon, acrylic, epoxy, thermoplastic elastomer rubber, acrylic polymer or copolymer, or combinations thereof. In some embodiments, the adhesive can have a crystalline and/or amorphous structure. In some embodiments, the adhesive 18 can have a glass transition temperature (T_{g}) that is above a maximum operating temperature of the photolithography system, to prevent the adhesive 18 from exceeding the Tg during operation of the system. It should be noted that FIGS. 1 and 2 are diagrammatic, and that in practice while the pellicle frame 16 may have a thickness of several millimeters by contrast the adhesive layer 18 is typically much thinner, e.g. the adhesive layer 18 may be a thin bonding layer on the order of a millimeter or less. Hence, from a particle adhesion viewpoint, the main concern is with particle adhering to the pellicle membrane 14 or frame 16, as opposed to particles adhering to the adhesive 18.

The pellicle cleaning system diagrammatically shown in FIGS. 1 and 2 includes an ultrasound transducer or transducer array 20 arranged respective to the pellicle 12 held by the pellicle holder 4 to apply an ultrasonic wave 22 to the pellicle 12, and more particularly to the pellicle membrane 14. In some embodiments, the ultrasound transducer or transducer array 20 produces a longitudinal ultrasonic wave 22 in which the pressure varies sinusoidally (or at least periodically) along the z-direction. In some embodiments, the ultrasonic wave 22 has a frequency of 20 kHz or greater, and in some embodiments has a frequency between 20 kHz and 2 MHz. The ultrasonic wave 22 may be applied continuously, or as a series of ultrasonic pulses. The longitudinal ultrasonic wave 22 induces a vibration 24 of the pellicle membrane 14 in the direction transverse to the plane of the pellicle membrane 14 (that is, and without loss of generality, in the z-direction using the x-y-z coordinate system of FIGS. 1 and 2). This vibration 24 can beneficially dislodge particles adhered to the pellicle membrane 14. The ultrasound transducer or transducer array 20 can comprise any suitable type of ultrasonic transducer, e.g. a piezoelectric crystal transducer or transducer array, a capacitive micromachined ultrasound transducer (CMUT) or transducer array, a piezoelectric micromachined ultrasound transducer (PMUT) or transducer array, or so forth, and is driven by a suitable ultrasonic power controller (UPC) 26.

Although the ultrasonic wave 22 applied by the ultrasonic transducer or transducer array 20 can be effective in dislodging particles from the pellicle membrane 14, it has some limitations as recognized herein. First, if the particles are electrostatically charged, this can strengthen the adherence of the particles to the membrane 14, potentially preventing the ultrasonic wave 22 from removing the particles. Second, even if a particle is dislodged, it could re-adhere at another position along the membrane 14, especially if the particle is electrostatically charged and thereby electromagnetically attracted to the pellicle membrane 14. Third, the ultrasonic wave 22 is much less effective, or possibly even wholly ineffective, at dislodging particles that may be adhered to the pellicle frame 16. Compared with the thin pellicle membrane 14 (e.g., 10-100 nanometer thickness in some examples), the pellicle frame 16 is far more massive and hence at best a greatly attenuated vibration will be induced in the more massive pellicle frame 16 when compared with the substantial vibration 24 induced in the thin membrane 14. In view of this recognition, the pellicle cleaning system diagrammatically shown in FIGS. 1 and 2 includes additional components that employ different physical mechanisms for removing particles adhered to the pellicle 12.

With continuing reference to FIGS. 1 and 2, the pellicle cleaning system further includes at least one ionizer 30, and in the illustrative embodiment two ionizers 30a and 30b (see front view of FIG. 2). The at least one ionizer 30 exposes the pellicle 12 to ionized gas generated by the at least one ionizer 30. In some embodiments, the at least one ionizer 30 comprises a radioisotope that emits alpha particles that ionize an input flow 32 of gas through the ionizer 30 to generate the ionized gas. Hence, the ionizer 30 may also be referred to herein as an alpha ionizer 30. Said another way, the at least one alpha ionizer 30 suitably comprises an alpha particle-emitting radioisotope, and the exposing of the pellicle 12 to the ionized gas includes flowing the input flow 32 of the gas through the alpha ionizer 30 so that alpha particles emitted by the alpha particle-emitting radioisotope interact with the input flow 32 of the gas to generate the ionized gas (e.g., by ionization of some molecules of the gas by emitted alpha particles). In one nonlimiting illustrative example, the alpha particle-emitting radioisotope may comprise polonium-210 (or, more generally, a material containing a suitable density of ²¹⁰Po atoms). In some embodiments, each alpha ionizer 30a, 30b includes a radioisotope producing radioactivity of at least 5 millicurie (mCi), so as to provide sufficient ionized molecule concentration in the ionized gas to provide the desired charge neutralization of particles adhered to the pellicle 12.

A purpose of exposing the pellicle 12 to the ionized gas generated by at least one alpha ionizer 30 is to neutralize static charge of any electrostatically charged particles adhered to the pellicle membrane 14 and/or to the pellicle frame 16. This neutralization occurs because unlike charges attract—hence, a negatively charged particle will attract positively charged ions of the ionized gas flow thus bringing positive electrical charge to neutralize the negative charge on the negatively charged particle. Similarly, a positively charged particle will attract negatively charged ions of the ionized gas flow thus bringing negative electrical charge to neutralize the positive charge on the positively charged particle. By neutralizing the electrical charge on any electrostatically charged particles adhered to the pellicle membrane 14, the electrostatic adhesion of such particles is removed, thus synergistically enhancing the ability of the membrane vibration 24 induced by the ultrasonic wave 22 to dislodge such now-neutralized particles.

Advantageously, alpha particles emitted by a typical alpha-emitting radioisotope such as ²¹⁰Po travel only a short distance in air, and do not penetrate human skin, thus ensuring safety of the pellicle cleaning apparatus incorporating the alpha ionizer(s) 30. Moreover, it is the ionized gas produced by the emitted alpha particles that is operative in the pellicle cleaning process, rather than the alpha particles themselves.

With particular reference to FIG. 1, the input flow 32 may comprise a gas such as nitrogen, clean dry air (CDA), or extreme clean dry air (XCDA). As diagrammatically shown in FIG. 1, the gas flow may be regulated by a mass flow controller (MFC) or other flow controller 34, and/or may optionally be filtered by a particulate filter 36 to ensure the input gas does not introduce particles to the pellicle 12. The diagrammatically shown illustrative gas handling system further includes an upstream gas shutoff valve 38.

The synergistic combination of applying the ultrasonic wave 22 to the pellicle 12 using the ultrasound transducer or transducer array 20 and simultaneously exposing the pellicle 12 to ionized gas generated by at least one alpha ionizer 30 is thus operative to enhance particle removal efficiency in dislodging particles from the membrane 14. However, as previously noted the ultrasonic wave 22 may be less effective at dislodging particles from the pellicle frame 16, and moreover there is still potential for the dislodged particles to re-adhere to either the pellicle membrane 14 or to the frame 16 (though this possibility of re-adhesion is reduced by neutralization of the static charge on the particles by action of the ionized gas, thus suppressing the electrostatic adhesion mechanism).

To address these further potential issues, the illustrative pellicle cleaning apparatus of FIGS. 1 and 2 further includes at least one gas nozzle 40, and in the illustrative embodiment two gas nozzles 40a and 40b (see side view of FIG. 1). The at least one gas nozzle 40 flows a gas on the pellicle 12. The gas may, for example, comprise nitrogen, clean dry air (CDA), or extreme clean dry air (XCDA). In the illustrative embodiment as shown in FIG. 1, the same gas supply that supplies the input gas 32 to the ionizers 30 also supplies gas to the nozzles 40a and 40b. However, it is contemplated to have separate gas supplies for the ionizer(s) and gas nozzle(s). In the illustrative embodiments, the gas nozzles 40a and 40b are designed as “blade nozzles”, which generate a flat curtain of gas flow.

The use of two gas nozzles 40a and 40b in the illustrative embodiment has advantages for cleaning the pellicle mount 16. As previously noted, the diagrammatically illustrated pellicle holder 4 includes a motor 6 or other mechanism for translating the held pellicle 12 in a reciprocating movement (indicated by arrow 42 in FIG. 1) in a positive direction (illustrative +y direction) and a negative direction (illustrative −y direction). As seen in FIG. 1, the first gas nozzle 40a is arranged to produce flow of the gas having a flow component in the positive direction (illustrative +y direction) as diagrammatically indicated by dashed arrows in FIG. 1. Conversely, the second gas nozzle 40b is arranged to produce flow of the gas having a flow component in the negative direction (illustrative −y direction). The magnitude of the component in the −y direction or +y direction depends on the angle of the gas nozzle 40 with respect to the plane of the pellicle membrane 14. In some nonlimiting illustrative embodiments, the gas nozzle 40 make an angle of between 10° and 30° respective to the plane of the pellicle membrane 14 (or, said another way, the gas nozzle 40 make an angle of between 10° and 30° respective to the x-y plane using the x-y-z coordinate system of FIGS. 1 and 2). In some non-limiting illustrative embodiments, the motor 6 operates to move the pellicle 12 in the −y direction or +y direction at a speed of between 5 mm/second and 25 mm/second.

In some embodiments, during movement of the pellicle 12 in the negative direction (illustrative −y direction), the gas is flowed on the pellicle 12 using the first nozzle 40a to produce the flow of the gas having the flow component in the positive direction (+y direction). During this pellicle movement in the negative direction, the second gas nozzle 40b is not used to flow gas. In this way, the inside edges of the pellicle frame 16 opposite the first nozzle 40a face the gas flow from the first nozzle 40a, thus providing gas flow on those inside edge to dislodge particles that may be adhered to those inside frame edges. In similar fashion, during movement of the pellicle 12 in the positive direction (+y direction), the gas is flowed on the pellicle 12 using the second nozzle 40b to produce the flow of the gas having the flow component in the negative direction (−y direction). During this pellicle movement in the positive direction, the first gas nozzle 40a is not used to flow gas. In this way, the inside edges of the pellicle frame 16 opposite the second nozzle 40b face the gas flow from the second nozzle 40b, thus providing gas flow on those inside edge to dislodge particles that may be adhered to those inside frame edges. To achieve this switching of operation of the first and second nozzles 40a and 40b, in the illustrative embodiment of FIG. 1 a first valve 44 is provided to shut off flow of the gas to the first gas nozzle 40a, and a second valve 46 is provided to shut off flow of the gas to the second gas nozzle 40b. A computer, electronic controller, or other electronic device comprising an electronic processor (not shown) may be programmed to control the motor 8 of the pellicle holder 4 and the valves 44 and 46 (which may be electrically actuated valves) to: (i) open first valve 44 to pass flow of the gas through the first gas nozzle 40a and close second valve 46 to stop flow of the gas through the second gas nozzle 40b when the motor 8 is moving the pellicle 12 in the negative direction (−y direction); and (ii) open second valve 46 to pass flow of the gas through the second gas nozzle 40b and close first valve 44 to stop flow of the gas through the first gas nozzle 40a when the motor 8 is moving the pellicle 12 in the positive direction (+y direction).

The gas nozzle(s) 40 also operate synergistically with the ultrasonic wave 22 generated by the ultrasound transducer or transducer array 20 to dislodge particles from the pellicle membrane 14, by providing forces operating in both the z-direction (from the longitudinal ultrasound wave 22 having pressure variation along the z-direction producing the vibration 24 of the membrane 14 in the z-direction) and in the y-direction (from the gas flow output by the nozzle(s) 40). These combined forces synergistically increase the particle removal efficiency in cleaning the pellicle membrane 14 and frame 16 as compared with either mechanism operating alone.

Furthermore, the ionizer(s) 30 operate synergistically with the gas nozzle(s) 40 to dislodge particles from both the pellicle membrane 14 and the frame 16. This is because neutralization of any electrostatically charged particles by the ionized gas output by the ionizer(s) 30 reduces or eliminates electrostatic adhesion of the particles, thus assisting the gas flow from the nozzle(s) 40 in dislodging the particles.

Thus, any two, or all three, of the mechanisms implemented by the pellicle cleaning apparatus of FIGS. 1 and 2 (namely ultrasonic wave, gas flow, and charge neutralization mechanisms) cooperatively operate together to enhance the particle removal efficiency.

In some embodiments, the pellicle cleaning apparatus of FIGS. 1 and 2 can be operated at atmospheric pressure, which is convenient as these embodiments do not require employing a pressure chamber. In other embodiments, the pellicle cleaning apparatus of FIGS. 1 and 2 is operated at an elevated pressure, for example at a pressure of between 1 and 10 atmospheres (i.e., between 100 kPa and 1 MPa). In these embodiments, the ambient in the pressure chamber may optionally be a controlled gas or gas mixture such as a pressurized nitrogen ambient or a pressurized CDA ambient.

In some embodiments, each gas nozzle 40 is designed as a blade nozzle which generates a flat curtain of gas flow using a nozzle aperture in the form of a slit or a linear array of apertures. Thus, the blade nozzle 40 provides a high gas flow rate at the surface of the pellicle 12 in the form of a flat curtain of gas flow, but with a low total volume of gas. This makes efficient use of the gas supply, and also reduces the likelihood of damaging the thin and fragile pellicle membrane 14. Moreover, the area of the pellicle 12 can be relatively large, for example some pellicles for EUV reticles can be rectangular with a maximum length on the order of several tens of centimeters. Hence, the flat curtain of gas flow from the blade nozzle 40 preferably extends in a linear direction on that order of length. To achieve these features, in some embodiments the nozzle 40 includes a nozzle aperture comprising a slit or a linear array of apertures arranged parallel with the pellicle membrane 14 of the pellicle 12 during the flowing of the gas via the nozzle 40. For the x-y-z coordinate system of FIGS. 1 and 2, this corresponds to the nozzle aperture comprising a slit or a linear array of apertures arranged in an x-y plane so as to be parallel with the pellicle membrane 14 which lies in an x-y plane. In some non-limiting illustrative embodiments, the flow of gas from the nozzle aperture is between 2 liters per minute and 10 liters per minute. That is, the gas flow controller 34 of FIG. 1 is configured to control the flow of the gas on the pellicle 12 via the at least one gas nozzle 40a, 40b to a flow rate that is between 2 liters per minute and 10 liters per minute.

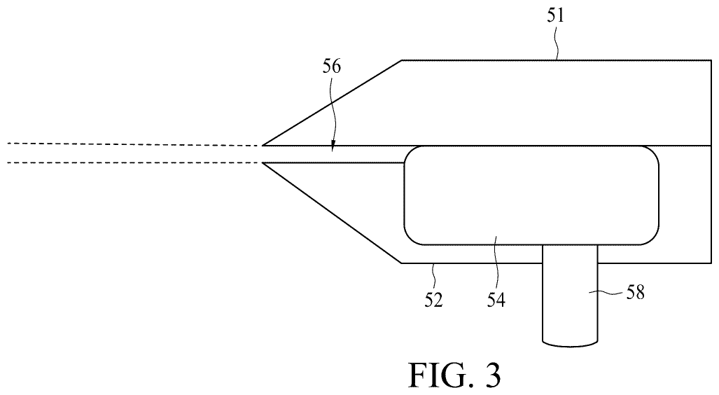

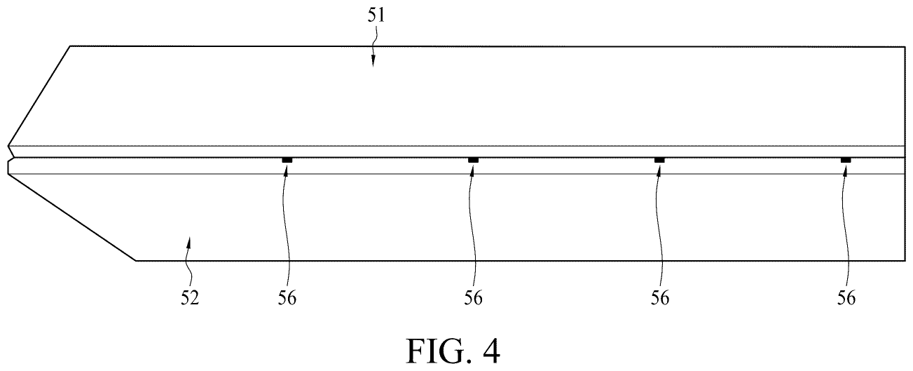

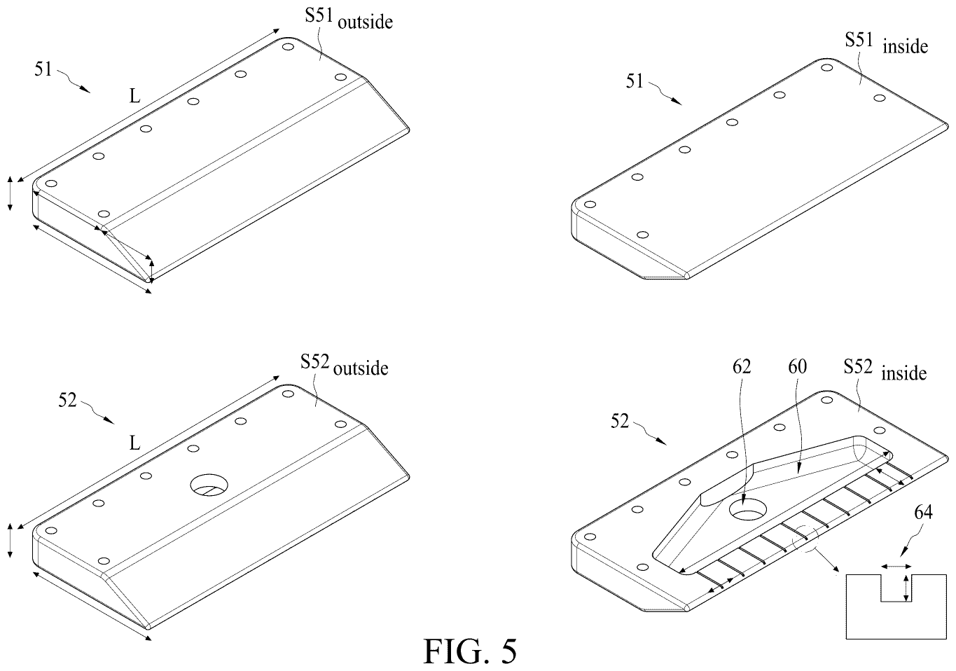

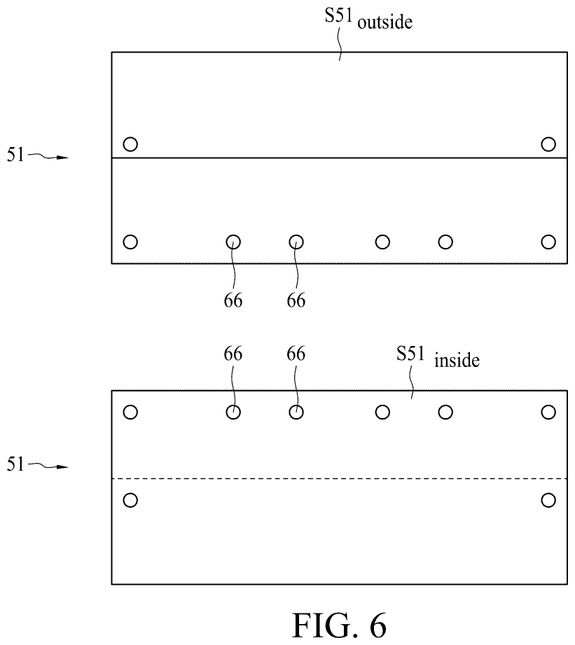

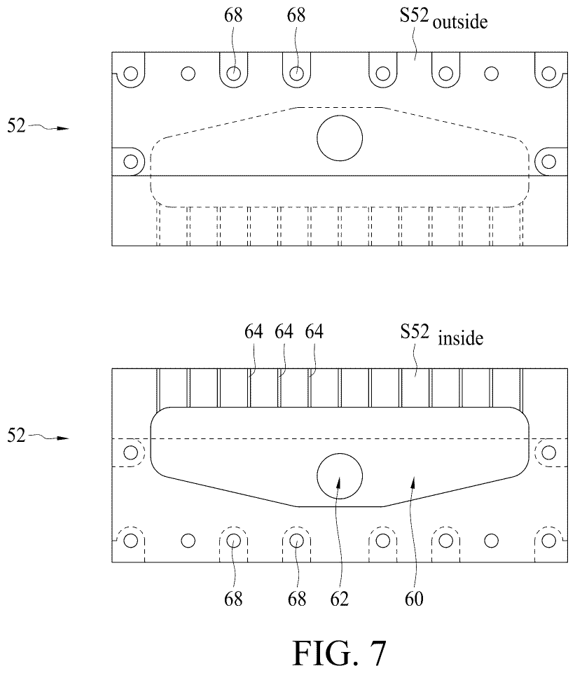

With reference to FIGS. 3-7, some illustrative embodiments of a blade nozzle 40 providing such a nozzle aperture comprising a slit or a linear array of apertures are described. As diagrammatically shown in FIG. 3, the illustrative nozzle 40 includes a first nozzle blade 51 and a second nozzle blade 52 that are secured together to form a plenum 54 between the first and second nozzle blades. FIG. 4 diagrammatically illustrates the nozzle aperture, which in the embodiment of FIG. 4 is a linear array of apertures 56, located at an interface between the first and second nozzle blades 51 and 52. By contrast, FIG. 3 shows the nozzle aperture 56 as a slit located at the interface between the first and second nozzle blades 51 and 52. The slit or linear array of apertures 56 is in fluid communication with the plenum 54, as diagrammatically shown in FIG. 3. A gas inlet 58 is also in fluid communication with the plenum 54 so as to admit the gas that is flowed by the gas nozzle 40 onto the pellicle into the plenum 54. Furthermore, FIG. 5 diagrammatically illustrates perspective views of: the outside surface S51_{outside} of first blade 51 and the inside surface S51_{inside} of the first blade 51 (upper views); and the outside surface S52_{outside} of second blade 52 and the inside surface S52_{inside} of the second blade 52 (lower views). The two inside surfaces S51_{inside} and S52_{inside} are secured together to form the gas nozzle 40, and the two outside surfaces S51_{outside} and S52_{outside} are outer surface of the gas nozzle 40. FIG. 6 diagrammatically illustrates the outside surface S51_{outside} of the first blade 51 (top view) and the inside surface S51_{inside} of the first blade 51 (bottom view), while FIG. 7 diagrammatically illustrates the outside surface S52_{outside} of the second blade 52 (top view) and the inside surface S52_{inside} of the second blade 52 (bottom view).

With reference to FIGS. 5-7, the inside surface S51_{inside} of the illustrative first blade 51 is planar, while the inside surface S52_{inside} of the illustrative second blade 52 has a recess 60 which forms the plenum 54 shown in FIG. 3. The illustrative second blade 52 further includes an opening 62 which forms (at least part of) the gas inlet 58 which is in fluid communication with the plenum 54 as seen in FIG. 3. This approach in which the plenum 54 is formed by a recess in the inside surface S52_{inside} of a single blade 52 is merely an illustrative design; in other variant designs, both blades can include recesses that combine when the inner surfaces are secured together to form the plenum 54. The inside surface S52_{inside} of the illustrative second blade 52 also includes grooves 64 that (after the inside surfaces S51_{inside} and S52_{inside} are secured together) form the linear array of apertures 56 shown in the example of FIG. 4. FIG. 5 shows a cross section of one groove 64 which in this illustrative example as a rectangular cross-section; however, other cross-sectional shapes for the grooves are contemplated. Again, this is merely an illustrative design; in other variant designs, both blades can include grooves that combine to form the array of apertures. In the case of a slit aperture such as that diagrammatically shown in FIG. 3, one or both of the inside surfaces suitably include a rabbet (i.e., a recess or groove cut into the edge of the inside surface) to from the slit aperture.

To facilitate assembly of the two blades 51 and 52 to form the gas nozzle 40, the illustrative blades 51 and 52 have respective openings 66 and 68 (labeled only in FIGS. 6 and 7) along the edges to allow for nut/bolt combinations, rivets, or other fasteners to secure the two blades 51 and 52 together. Other approaches for securing the two blades 51 and 52 together with their facing inside surfaces S51_{inside} and S52_{inside} in contact are contemplated, such as welding, clamping, or so forth. In some manufacturing embodiments, the opening 62 in the second blade 52 providing access to the plenum 54 is a threaded opening, and a gas inlet tube with a threaded end is secured with the threaded opening 62 to complete the gas inlet 58.

The slit or linear array of apertures 56 advantageously forms a flat gas curtain that can extend along the width of the pellicle 12 in the x-direction (referring to the x-y-z coordinate system of FIGS. 1 and 2), thus in combination with the translation of the pellicle 12 by operation of the motor 8 enabling gas flow to contact the entire surface of the pellicle 12, without expending an excessive volume of the gas which could disadvantageously introduce turbulence. By comparison, a nozzle that generates a more three-dimensional conical air curtain would use a higher volume of gas and is more prone to generating turbulence. To clean the entire pellicle membrane 14 using the air nozzles 40, the length L (indicated only in FIG. 5) of the blades 51 and 52 along the direction of the slit or linear array of apertures 56 (i.e., along the x-direction) should be sufficient to enable the gas nozzle 40 to flow the gas out of the nozzle aperture over the entire area of the pellicle 12. For a typical pellicle sized on the order of several tens of centimeters per side, the length L is thus suitably also on the order of several tens of centimeters or more, e.g. 120 cm in one nonlimiting illustrative example.

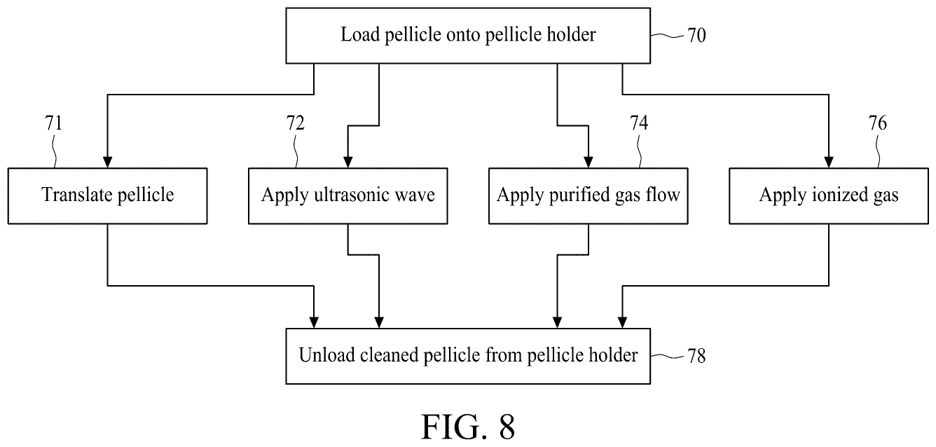

With reference now to FIG. 8, an illustrative pellicle cleaning method suitably performed by the pellicle cleaning apparatus of FIGS. 1 and 2 is described. In an operation 70, the pellicle 12 is loaded onto the pellicle holder 4, for example by securing the pellicle 12 to the clamp 6. Operation 70 of translating (or reciprocating) the pellicle 12 using the motor 8, operation 72 of applying the ultrasonic wave 22 using the ultrasound transducer or transducer array 20, operation 74 of applying the purified gas flow via the one or more gas nozzles 40, and operation 76 of applying the ionized gas using the one or more ionizers 30, are then performed simultaneously to dislodge particles by the synergistic combination of forces applied in the z-direction (via the ultrasonic wave) and in the y-direction (via the gas nozzles) and electrostatic charge neutralization (via the ionized gas). The process may be performed for one, two, or more repeating cycles (i.e. reciprocations) of the positive direction/negative direction movement cycle. As previously noted, in some nonlimiting embodiments employing the illustrative two gas nozzles 40a and 40b, only the first gas nozzle 40a may be operating during movement in the negative direction (−y direction) while only the second gas nozzle 40b may be operating during movement in the positive direction (+y direction). Finally, after the cleaning is complete in an operation 78 the cleaned pellicle 12 is removed from the pellicle holder 4 and may then be affixed onto a EUV reticle via the pellicle frame 16 (or placed into storage, or otherwise utilized or stored). For example, the reticle with the affixed pellicle may be loaded to an exposing chamber. After the loading and in the exposing chamber, light is exposed on a photoresist layer disposed on a substrate using the reticle to form a patterned photoresist layer. A circuit layout pattern is formed by developing and etching the patterned photoresist layer.

The disclosed pellicle cleaning apparatuses and methods advantageously provide high particle removal efficiency by the disclosed gas nozzle design and the disclosed dynamic control sequence of nozzle flow to reduce turbulence and disengage particles located on the pellicle frame 16 (including corners, vent holes, or other features thereof) so as to reduce or eliminate particles falling from the pellicle onto the reticle during EUV lithography. Use of the disclosed gas nozzles 40, alpha ionizers 30, and ultrasonic wave 22 provides three coadunate physical forces that operate together to remove particles from the EUV pellicle membrane 14 and frame 16. Advantageously, both the pellicle membrane 14 and the pellicle frame 16 are cleaned by these three coadunate physical forces.

In the following, some further embodiments are described.

In a nonlimiting illustrative embodiment, a pellicle cleaning method comprises: flowing a gas on a pellicle comprising a pellicle membrane mounted on a pellicle frame using at least one gas nozzle; during the flowing, moving the pellicle respective to the at least one gas nozzle; during the flowing, exposing the pellicle to ionized gas generated by at least one alpha ionizer; and during the flowing, applying ultrasonic wave to the pellicle using an ultrasound transducer or transducer array.

In a nonlimiting illustrative embodiment, a method of circuit layout patterning includes: performing a pellicle cleaning method as set forth in the immediately preceding paragraph on a pellicle comprising a pellicle membrane mounted on a pellicle frame; after the pellicle cleaning method is performed, affixing the pellicle to a reticle; loading the reticle with the affixed pellicle to an exposing chamber; after the loading and in the exposing chamber, exposing light on a photoresist layer disposed on a substrate using the reticle to form a patterned photoresist layer; and forming a circuit layout pattern by developing and etching the patterned photoresist layer.

In a nonlimiting illustrative embodiment, a pellicle cleaning apparatus includes a pellicle holder, at least one gas nozzle arranged to flow a gas on an associated pellicle held by the pellicle holder, and at least one ionizer arranged to expose the associated pellicle held by the pellicle holder to ionized gas. In some embodiments, the apparatus further includes an ultrasound transducer or transducer array arranged to apply an ultrasonic wave to the associated pellicle held by the pellicle holder.

In a nonlimiting illustrative embodiment, a pellicle cleaning apparatus includes a pellicle holder, a gas nozzle arranged to flow a gas on an associated pellicle held by the pellicle holder, and an ultrasound transducer or transducer array arranged to apply an ultrasonic wave to the associated pellicle held by the pellicle holder. The gas nozzle has a nozzle aperture comprising a slit or a linear array of apertures arranged parallel with a pellicle membrane of the pellicle.

In some embodiments of the pellicle cleaning apparatus of the immediately preceding paragraph, the gas nozzle includes first and second nozzle blades that are secured together to form a plenum between the first and second nozzle blades. A gas inlet is in fluid communication with the plenum for the gas that is flowed on the pellicle to enter the plenum. The slit or linear array of apertures is located at an interface between the first and second nozzle blades, and the slit or linear array of apertures is in fluid communication with the plenum.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A pellicle cleaning apparatus comprising:
a pellicle holder configured to hold an associated pellicle and to move the associated pellicle held by the pellicle holder;
at least one gas nozzle arranged to flow a gas on the associated pellicle held by the pellicle holder while the pellicle holder moves the associated pellicle;
at least one alpha ionizer arranged to expose the associated pellicle held by the pellicle holder to ionized gas generated by the at least one alpha ionizer; and
an ultrasound transducer or transducer array arranged to apply an ultrasonic wave to the associated pellicle held by the pellicle holder.

2. The pellicle cleaning apparatus of claim 1 wherein:
the pellicle holder is configured to alternate between moving the associated pellicle in a positive direction respective to the at least one nozzle and moving the associated pellicle in a negative direction respective to the at least one nozzle;
the at least one gas nozzle includes a first gas nozzle arranged to produce flow of the gas having a flow component in the positive direction during the movement of the pellicle in the negative direction; and
the at least one gas nozzle further includes a second gas nozzle arranged to produce flow of the gas having a flow component in the negative direction during the movement of the pellicle in the positive direction.

3. The pellicle cleaning apparatus of claim 2 wherein:
during the movement of the pellicle in the positive direction, the first gas nozzle does not produce flow of the gas; and
during the movement of the pellicle in the negative direction, the second gas nozzle does not produce flow of the gas.

4. The pellicle cleaning apparatus of claim 1 wherein the at least one gas nozzle includes a nozzle aperture comprising a slit or a linear array of apertures arranged parallel with the pellicle membrane of the associated pellicle held by the pellicle holder.

5. The pellicle cleaning apparatus of claim 1 wherein the at least on gas nozzle is configured to flow the gas on the associated pellicle held by the pellicle holder at a flow rate between 2 liters per minute and 10 liters per minute.

6. The pellicle cleaning apparatus of claim 1 wherein each alpha ionizer includes a radioisotope producing radioactivity of at least 5 millicurie (mCi).

7. The pellicle cleaning apparatus of claim 1 wherein the at least one alpha ionizer comprises an alpha particle-emitting radioisotope, and is configured to generate the ionized gas by ionizing an input flow of the gas through the alpha ionizer wherein alpha particles emitted by the alpha particle-emitting radioisotope interact with the input flow of the gas to generate the ionized gas.

8. The pellicle cleaning apparatus of claim 7 wherein the alpha particle-emitting radioisotope comprises polonium-210.

9. The pellicle cleaning apparatus of claim 1 wherein the ultrasound transducer or transducer array is configured to generate the ultrasonic wave at a frequency between 20 kHz and 2 MHz.

10. A pellicle cleaning apparatus comprising:
a pellicle holder;
at least one gas nozzle arranged to flow a gas on an associated pellicle held by the pellicle holder; and
at least one ionizer arranged to expose the associated pellicle held by the pellicle holder to ionized gas.

11. The pellicle cleaning apparatus of claim 10 further comprising:
an ultrasound transducer or transducer array arranged to apply ultrasonic wave to the associated pellicle held by the pellicle holder.

12. The pellicle cleaning apparatus of claim 10 wherein the pellicle holder is configured to move the associated pellicle held by the pellicle holder while the at least one gas nozzle flows the gas on the pellicle.

13. The pellicle cleaning apparatus of claim 12 wherein:
the at least one gas nozzle includes a first gas nozzle arranged to produce flow of the gas having a flow component in a positive direction and a second gas nozzle arranged to produce flow of the gas having a flow component in a negative direction;
the pellicle holder is configured to alternate between moving the pellicle in the positive direction and moving the pellicle in the negative direction; and
the first and second gas nozzles are configured to:
(i) during movement of the pellicle in the negative direction, flow the gas on the pellicle using the first nozzle while not flowing the gas using the second gas nozzle, and
(ii) during movement of the pellicle in the positive direction, flow the gas on the pellicle using the second nozzle while not flowing the gas using the first gas nozzle.

14. The pellicle cleaning apparatus of claim 10 wherein the at least one gas nozzle includes a nozzle aperture comprising a slit or a linear array of apertures arranged parallel with a pellicle membrane of the pellicle.

15. The pellicle cleaning apparatus of claim 14 wherein the at least one gas nozzle includes:
first and second nozzle blades that are secured together to form a plenum between the first and second nozzle blades; and
a gas inlet in fluid communication with the plenum for the gas that is flowed on the pellicle to enter the plenum;
wherein the slit or linear array of apertures is located at an interface between the first and second nozzle blades, and the slit or linear array of apertures is in fluid communication with the plenum.

16. The pellicle cleaning apparatus of claim 10 further comprising:
a gas flow controller configured to control the flow of the gas on the associated pellicle via the at least one gas nozzle to a flow rate that is between 2 liters per minute and 10 liters per minute.

17. The pellicle cleaning apparatus of claim 10 wherein the at least one ionizer comprises a radioisotope emitting alpha particles that ionize an input flow of the gas through the ionizer to generate the ionized gas.

18. The pellicle cleaning apparatus of claim 17 wherein the radioisotope comprises polonium-210.

19. A pellicle cleaning apparatus comprising:
a pellicle holder;
a gas nozzle arranged to flow a gas on an associated pellicle held by the pellicle holder, the gas nozzle having a nozzle aperture comprising a slit or a linear array of apertures arranged parallel with a pellicle membrane of the pellicle; and
an ultrasound transducer or transducer array arranged to apply an ultrasonic wave to the associated pellicle held by the pellicle holder.

20. The pellicle cleaning apparatus of claim 19 wherein the gas nozzle includes:
first and second nozzle blades that are secured together to form a plenum between the first and second nozzle blades; and
a gas inlet in fluid communication with the plenum for the gas that is flowed on the pellicle to enter the plenum;
wherein the slit or linear array of apertures is located at an interface between the first and second nozzle blades, and the slit or linear array of apertures is in fluid communication with the plenum.
